(19) United States
(12) Patent Application Publication
(10) Pub. No.: US 2001/0031321 A1
(43) Pub. Date: Oct. 18, 2001

(54) Film forming method in which flow rate is switched

(76) Inventor: Shigeo Ishikawa, Tokyo (JP)

Correspondence Address: SUGHRUE, MION, ZINN, MACPEAK & SEAS, 2100 Pennsylvania Avenue, N.W., Washington, DC, 20037, US

(21) Appl. No.: 09/832,093

(22) Filed: Apr. 11, 2001

(30) Foreign Application Priority Data
Apr. 18, 2000 (JP) 117008/2000

(51) Int. Cl. C23C 16/00; H01L 21/31

(52) U.S. Cl. 427/569; 427/255.27

(57) ABSTRACT

In a method of forming a film, the supply of a reaction gas is started at a first flow rate into a chamber in which a plasma is formed, such that an initial film is formed on a wafer. Then, the supply of the reaction gas is started at a second flow rate into the chamber in which the plasma is formed, such that the film is formed on the initial film, the first flow rate being smaller than the second flow rate.

### BACKGROUND OF THE INVENTION

1. Field of the Invention

The present invention relates to a film forming method using a plasma CVD apparatus for a semiconductor device.

2.Description of the Related Art

There has been arisen a problem of destruction of a gate oxide film formed by a plasma CVD apparatus with thinning of a pattern in an LSI. Particularly, when a high density plasma (HDP) is used for a filling process of an interline space with a high aspect ratio in a plasma CVD process, a gate oxide film is often destroyed by electrons or ions in the plasma.

When an oxide film is formed by use of a conventional plasma CVD apparatus, high frequency power is applied after gases such as O₂, Ar and N₂ are introduced into a reaction chamber. Then, when the plasma is stabilized, gases such as SiH₄, SiF₄ and TEOS are introduced into the chamber. Alternatively, gases such as SiH₄, SiF₄ and TEOS are introduced into the chamber at the same time as the application of the high frequency power.

FIGS. 2A to 2E are conventional timing charts when gases are introduced into a reaction chamber, when an oxide film is formed in the following procedure. A wafer is introduced into the chamber and is placed on a stage. O₂ gas is introduced into the chamber, and at the same time Ar gas is introduced into the chamber. After the gas flow rates of the respective introduced gases are stabilized, high frequency power is applied from a high frequency power source to generate a plasma. The generated plasma increases the temperature of the wafer to a temperature in a range of 200 to 400° C. Then, SiH₄ gas is introduced into the chamber. Then, a bias power is applied to the wafer by a high frequency source connected to the stage. The application of the bias power is carried out at the same time as the introduction of the SiH₄ gas into the chamber or after several seconds. The SiH₄ gas is supplied through two pipes and the gas flow rates for the respective pipes are set to different values by mass flow controllers. In particular, the gas flow rate supplied through one pipe is set to a level appropriately between one fifth and one tenth of the gas flow rate supplied through the other pipe.

In this case, the film is initially formed from a region of the wafer where a nozzle of the other pipe is provided, i.e., from a peripheral region of the wafer. Therefore, the film cannot be uniformly formed over the whole wafer surface at the initial step, and the center region of the wafer has a thinner thickness. In such a situation, when a large amount of electrons and ions are injected on the whole wafer surface, insulating breakdown of a gate oxide film formed in the center region is deteriorated.

FIG. 5 shows gate breakdown voltages in gate oxide films of transistors prepared by such a film forming technique, when wiring lengths are 320 μm, 2030 μm, 80320 μm and 320320 μm, respectively. In general, a gate leak current is 10⁻¹² A or less in case of the gate voltage of 2.5 V. In the gate oxide film formed by the conventional method, the breakdown voltage is deteriorated and a current larger than 10⁻¹² A flows. It would be understood that the deterioration becomes more serious as the wiring length becomes longer.

In case that an oxide film is formed by the conventional plasma CVD apparatus as mentioned above, the gate oxide film is deteriorated at an initial stage of the film forming process.

In conjunction with the above description, a CVD method of compound semiconductor is disclosed in Japanese Laid Open Patent Application (JP-A-Heisei 3-150294). In this reference, an epitaxial growth gas and a doping gas are supplied into a reaction chamber in which a semiconductor substrate is located. In this case, the introduction start timing of the doping gas is made later than that of the epitaxial growth gas. For example, the doping gas starts to be supplied after at least one molecule layer of a compound semiconductor layer which does not contain impurity is formed. Thus, the impurity-doped compound semiconductor layer is formed on the semiconductor substrate.

Also, an insulating film used for a semiconductor device is disclosed in Japanese Laid Open Patent Application (JP-A-Heisei 9-289209). In this reference, a CVD film is formed from material gas containing a gas which has a Si—H coupling as an interlayer insulating film or a passivation film. In this case, a quantity of Si—H couplings in the CVD film is adjusted to be equal to or less than 0.6×10²¹ cm⁻³ to restrain the generation of electron traps in a gate oxide film or a tunnel oxide film and to prevent the change of a threshold value of a transistor. Also, a refractive index of the CVD film is adjusted to be equal to or more than 1.65 or nitrogen concentration in the CVD film is adjusted to be equal to or more than 3×10²¹ cm⁻³, for improvement of moisture resistance.

### SUMMARY OF THE INVENTION

Therefore, an object of the present invention is to provide a film forming method of forming a plasma oxide film whose breakdown voltage is not deteriorated.

In an aspect of the present invention, a method of forming a film, is attained by (a) starting supply of a reaction gas at a first flow rate into a chamber in which a plasma is formed, such that an initial film is formed on a wafer; and by (b) starting supply of the reaction gas at a second flow rate into the chamber in which the plasma is formed, after the step (a), such that the film is formed on the initial film, the first flow rate being smaller than the second flow rate.

Here, the reaction gas may be a compound gas containing Si. In this case, it is desirable that the reaction gas is one of SiH₄, SiF₄ and TEOS.

Also, it is desirable that the step (b) is carried out 1 to 10 seconds after the step (a) is carried out.

Also, the first flow rate may be in a range of one fifth to one tenth of the second flow rate.

Also, in the (a) starting step, the supply of the reaction gas at the first flow rate into the chamber is started via a first nozzle, and the first nozzle may be provided on the chamber above a center region of the wafer.

Also, in the (b) starting step (b), the supply of the reaction gas at the second flow rate into the chamber is started via second nozzles, and the second nozzles may be provided on side walls of the chamber above the wafer.

In another aspect of the present invention, a method of forming a film, is attained by (a) forming a film from a center region of a wafer by supplying a reaction gas, while a thickness of the film is equal to or thinner than 10 mm; and by (b) forming the film on whole of the wafer, by supplying the reaction gas, after the step (a).

The (a) forming step may be attained by supplying the reaction gas at a first flow rate, the (b) forming step may be attained by supplying the reaction gas at a second flow rate, and the first flow rate may be in a range of one fifth to one tenth of the second flow rate.

Also, the reaction gas may be a compound gas containing Si, and the reaction gas desirably is one of SiH₄, SiF₄ and TEOS.

Also, it is desirable that the (b) forming step is carried out 1 to 10 seconds after the step (a) is carried out.

Also, when the (a) forming step is attained by starting supply of the reaction gas at the first flow rate into the chamber via a first nozzle, the first nozzle may be provided on the chamber above a center region of the wafer.

Also, when the (b) forming step is attained by starting supply of the reaction gas at the second flow rate into the chamber via second nozzles, the second nozzles may be provided on side walls of the chamber above the wafer.

### BRIEF DESCRIPTION OF THE DRAWING

FIGS. 1A to 1E are timing charts showing operation timings in the present invention;

FIGS. 2A to 2E are timing charts showing operation timings in a conventional method;

FIG. 3 is a diagram showing the structure of a plasma CVD apparatus;

FIG. 4 is a diagram showing a relation of gate current and accumulated failure percentage in transistors formed by the present invention; and

FIG. 5 is a diagram showing a relation of gate current and accumulated failure percentage in transistors formed by the conventional method.

### DESCRIPTION OF THE PREFERRED EMBODIMENTS

A film forming method of the present invention will now be described below in detail with reference to the attached drawings.

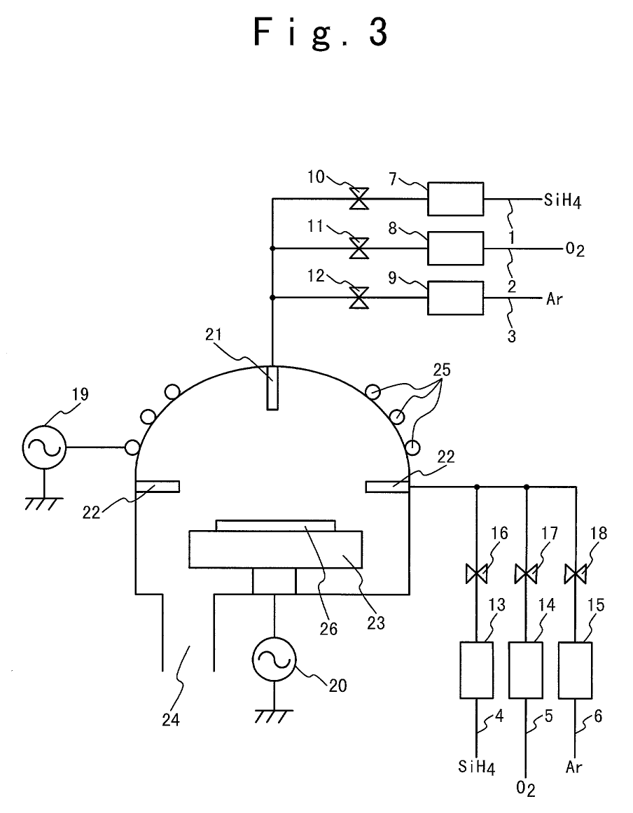

FIG. 3 illustrates the structure of an HDP-CVD apparatus. Referring to FIG. 3, the plasma CVD apparatus in this embodiment is composed of a reaction chamber formed of ceramic material in the form of a dome. A source coil 25 is wound in an upper side portion of the chamber. When the power is applied from a high frequency power source 19 to the source coil 25, a source plasma is generated. A stage 23 is provided in a lower portion of the chamber and a wafer 26 is mounted on the stage 23. The stage 23 has an electric static chuck (ESC) and when bias power is supplied from a bias power source 20 to the stage 23, the plasma film forming process is started using the source plasma. A portion of the bottom of the chamber is provided with an exhaust port 24 connected to a turbo molecular vacuum pump (TMP). A gas nozzle 21 is provided on the top portion of the chamber above the center portion of the stage 23 to feed a reaction gas at a small flow rate. A plurality of gas nozzles 22 are provided on the side portion of the chamber on positions lower than the source coil 25 but upper than the wafer 26 such that the reaction gas can be supplied at a large flow rate from the peripheral portion of the wafer 26 on the stage 23. Each of the gas nozzles 22 is directed to the center portion of the wafer 26.

SiH₄ gas as the reaction gas is supplied from the nozzle 21 to the chamber through a mass flow controller (MFC) 7, a valve 10 and pipe 1. O₂ gas is supplied from the nozzle 21 to the chamber through a mass flow controller (MFC) 8, a valve 11 and pipe 2. Ar gas is supplied from the nozzle 21 to the chamber through a mass flow controller (MFC) 9, a valve 12 and pipe 3. SiH₄ gas as the reaction gas is supplied from the nozzle 22 to the chamber through a mass flow controller (MFC) 13, a valve 16 and pipe 4. O₂ gas is supplied from the nozzle 22 to the chamber through a mass flow controller (MFC) 14, a valve 17 and pipe 5. Ar gas is supplied from the nozzle 22 to the chamber through a mass flow controller (MFC) 15, a valve 18 and pipe 6.

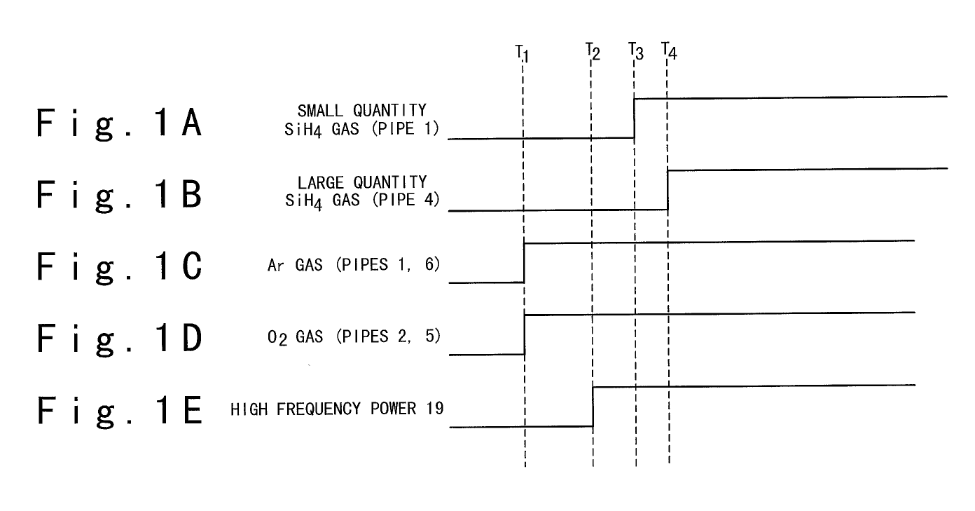

FIGS. 1A to 1E are timing charts showing the operation timings when gases are introduced and power is applied, in the embodiment of the present invention. The procedure for forming an oxide film will be carried out as shown in the timing charts of FIGS. 1A to 1E.

After the wafer 26 is disposed on the stage 23 within the chamber, the chamber is supplied simultaneously at the timing T1 with the O₂ gas via the pipes 2 and 5, and the Ar gas is supplied via the Ar gas pipes 3 and 6, as shown in FIGS. 1C and 1D. When the flow rates of these gases enter in stable states, high frequency power is applied from the high frequency power source 19 to the source coil 25 to generate a plasma in the chamber at the timing T2 as shown in FIG. 1E. The generated plasma increases the temperature of the wafer 26 in a range of 200 to 400° C. When the temperature of the wafer 26 reaches a temperature of 200 to 400° C., SiH₄ gas is introduced into the chamber through the SiH₄ gas pipe 1 at the timing T3 as shown in FIG. 1A. Then, the SiH₄ gas is introduced into the chamber through the SiH₄ gas pipe 4 at the timing T4, 1 to 10 seconds after the supply of the SH₄ gas through the pipe 1 as shown in FIG. 1B.

The bias power is applied from the high frequency power source 20 to the stage 23. At this time, the application of the bias power is carried out at a timing between the introduction of the SiH₄ gas from the SiH₄ gas pipe 1 to the chamber and the introduction of the SiH₄ gas from the SiH₄ gas pipe 4 to the chamber, or after the introduction of the SiH₄ gas from the SiH₄ gas pipe 4 to the chamber.

The flow rates of the SiH₄ gases from the SiH₄ gas pipes 1 and 4 are controlled to different values by the mass flow controllers 7 and 13 which are controlled by a controller (not shown). Particularly, the gas flow rate in the SiH₄ gas pipe 1 is used such that a uniform film can be formed on the wafer 26 when the film thickness is equal to or less than 10 nm. That is, the gas flow rate in the SiH₄ gas pipe 1 is set to an appropriate value between one fifth and one tenth of that in the SiH₄ gas pipe 4. More specifically, the gas flow rate in the SiH₄ gas pipe 1 is 10 SCCM and the gas flow rate in the SiH₄ gas pipe 4 is 70 SCCM.

As described in the embodiment, by feeding the SiH₄ gas from the gas pipe having the mass flow controller 7 at a small flow rate into the chamber via the gas nozzle 21, the film can be uniformly formed initially from the center region of the wafer 26 above which the gas nozzle 21 is provided, to the periphery of the wafer 26, while the film has the thickness of 10 nm or less. Thereafter, by feeding the SiH₄ gas from the gas pipe into the chamber via the gas nozzle 22, the film can be rapidly formed. Thus, it is possible to reduce the ununiformity due to the formation of the film from the peripheral portion of the wafer at the initial film forming step.

In such a manner, when the oxide film is firstly formed on the center region of the wafer 26 at an initial film forming step, the deterioration of the insulating breakdown of a gate oxide film can be avoided because an amount of injected charges into the wafer become uniform at the initial film forming step.

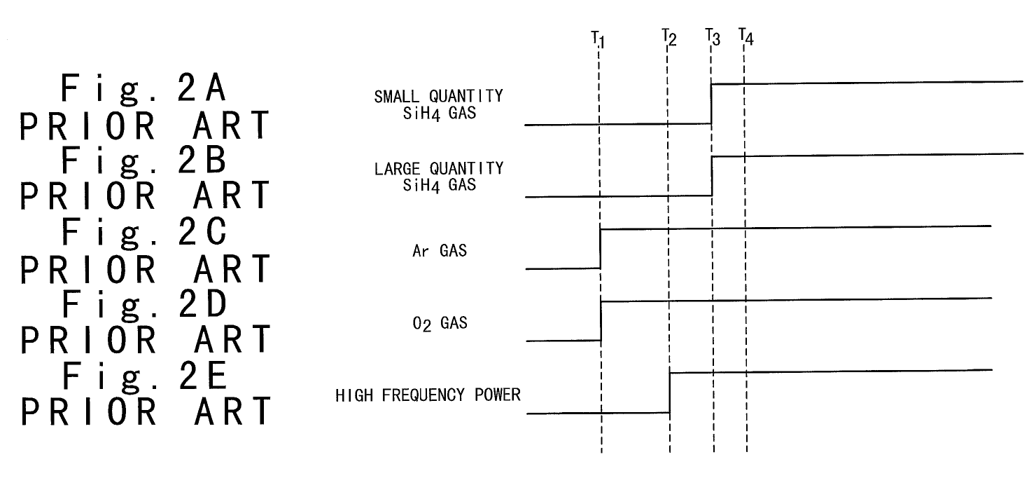

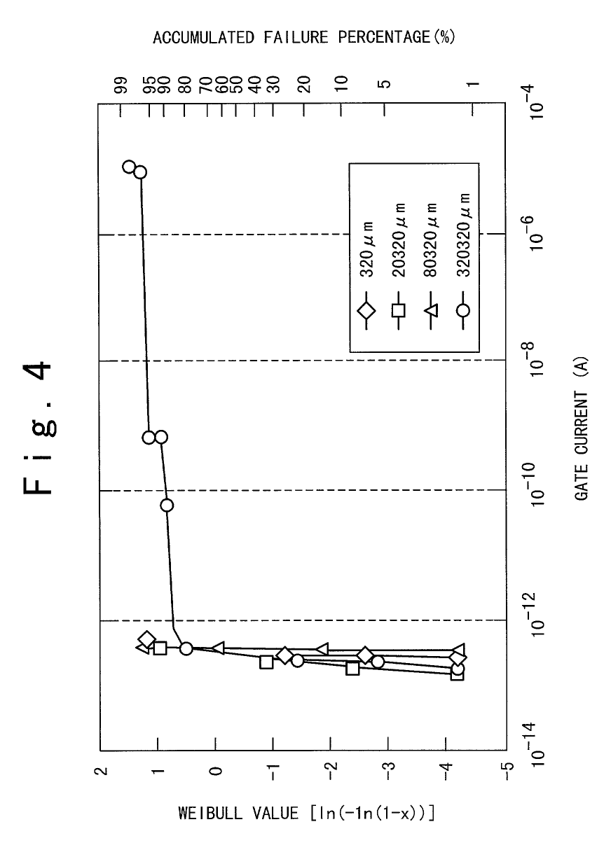

FIG. 4 illustrates gate voltages and accumulated failure percentage in transistors each having an oxide film formed in such a manner, when the wiring lengths are 320 μm, 20320 μm, 80320 μm and 320320 μm, respectively. In general, a gate leak current is 10⁻¹² A or less in case of the gate voltage of 2.5 V. In the gate oxide film formed by the method according to the present invention, it would be understood that the deterioration of the breakdown voltage of the gate oxide film is remarkably improved, as compared with that of the transistors formed in accordance with the conventional method as shown in FIGS. 2A to 2E.

In the above embodiment, a large amount of gas is supplied from the gas nozzle 22 into the chamber with the delay of 1 to 10 seconds after the supply of a small amount of gas from the gas nozzle 21 into the chamber. The delay time that is shorter than 1 second or longer than 10 seconds is not suitable. When the delay time is shorter, the film formation is commenced from the peripheral region of the wafer. On the other hand, when the delay time is longer, the characteristic of the initial oxide film is deteriorated and thus the insulating breakdown of the oxide film occurs.

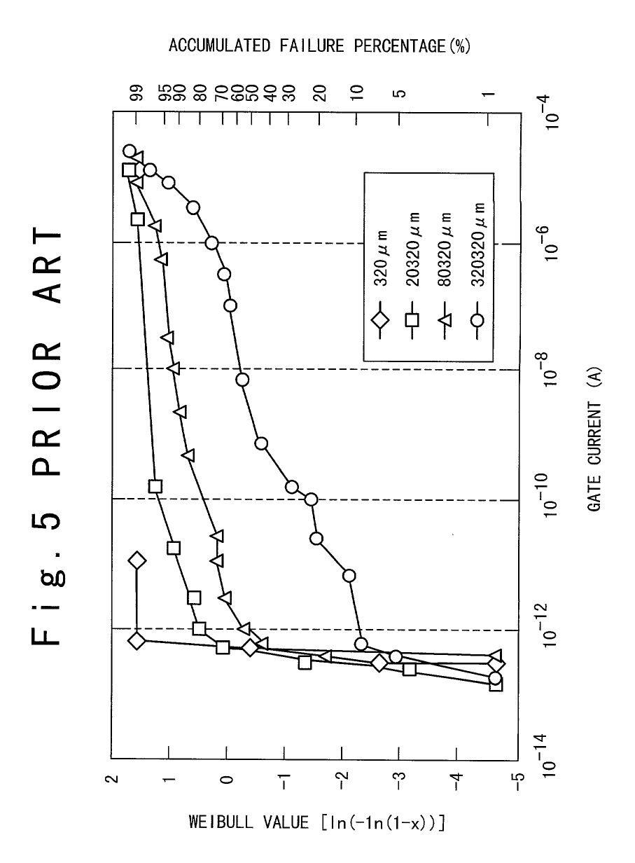

In the above mentioned embodiment, there has been described about the case that a small amount of SiH₄ gas is fed to the center region of the wafer 26 via the gas nozzle 21. However, if the gas nozzle 21 is slightly displaced from the center region of the wafer 26, it was found that the breakdown voltage of the gate oxide film could be significantly improved, as compared with that of the conventional gate oxide film as shown in FIG. 5.

As mentioned above, according to the present invention, semiconductor elements in which the breakdown voltage of agate oxide film is not deteriorated can be provided by feeding a small amount of gas prior to the feeding a large amount of gas in such a manner that the film formation is commenced from the center region of the wafer.

What is claimed is:

1. A method of forming a film, comprising the steps of:
(a) starting supply of a reaction gas at a first flow rate into a chamber in which a plasma is formed, such that an initial film is formed on a wafer; and
(b) starting supply of the reaction gas at a second flow rate into the chamber in which the plasma is formed, after said step (a), such that the film is formed on the initial film, the first flow rate being smaller than the second flow rate.

2. The method according to claim 1, wherein said reaction gas is a compound gas containing Si.

3. The method according to claim 2, wherein said reaction gas is one of SiH₄, SiF₄ and TEOS.

4. The method according to claim 1, wherein said step (b) is carried out 1 to 10 seconds after said step (a) is carried out.

5. The method according to claim 1, wherein said first flow rate is in a range of one fifth to one tenth of said second flow rate.

6. The method according to claim 1, wherein said step (a) comprises the step of:
starting supply of the reaction gas at the first flow rate into the chamber via a first nozzle, and
said first nozzle is provided on the chamber above a center region of the wafer.

7. The method according to claim 1, wherein said step (b) comprises the step of:
starting supply of the reaction gas at the second flow rate into the chamber via second nozzles, and
said second nozzles are provided on side walls of the chamber above the wafer.

8. A method of forming a film, comprising the steps of:
(a) forming a film from a center region of a wafer by supplying a reaction gas, while a thickness of the film is equal to or thinner than 10 nm; and
(b) forming the film on whole of said wafer, by supplying the reaction gas, after said step (a).

9. The method according to claim 8, wherein said step (a) comprises the step of:
supplying said reaction gas at a first flow rate,
said step (b) comprises the step of:
supplying said reaction gas at a second flow rate, and
said first flow rate is in a range of one fifth to one tenth of said second flow rate.

10. The method according to claim 8, wherein said reaction gas is a compound gas containing Si.

11. The method according to claim 10, wherein said reaction gas is one of SiH₄, SiF₄ and TEOS.

12. The method according to claim 8, wherein said step (b) is carried out 1 to 10 seconds after said step (a) is carried out.

13. The method according to claim 8, wherein said step (a) comprises the step of:
starting supply of the reaction gas at the first flow rate into the chamber via a first nozzle, and
said first nozzle is provided on the chamber above a center region of the wafer.

14. The method according to claim 8, wherein said step (b) comprises the step of:
starting supply of the reaction gas at the second flow rate into the chamber via second nozzles, and
said second nozzles are provided on side walls of the chamber above the wafer.
